(19) United States
(12) Patent Application Publication
(10) Pub. No.: US 2026/0285177 A1
(43) Pub. Date: Sep. 24, 2026

(54) ANODE VOLTAGE BASED BATTERY CONTROL

(71) Applicant: FORD GLOBAL TECHNOLOGIES, LLC, Dearborn, MI (US)

(72) Inventors: Arnold Kweku Mensah-Brown, Canton, MI (US); Donnell Matthew Washington, Northville, MI (US); Thomas J Coupar, Ann Arbor, MI (US)

(21) Appl. No.: 19/086,659

(22) Filed: Mar. 21, 2025

(51) Int. Cl. B60L 53/20; B60L 50/60; G01R 31/382; G01R 31/396; H01M 10/42; H01M 10/44; H01M 10/48

(52) U.S. Cl. CPC B60L 53/20; B60L 50/60; G01R 31/382; G01R 31/396; H01M 10/425; H01M 10/441; H01M 10/486; B60L 2240/547; H01M 2010/4271

(57) ABSTRACT

A system incorporates ultrasonic transducers to collect time-of-flight data, which, along with full-cell-voltage and temperature data, enables monitoring of the battery's anode voltage. A controller adjusts the magnitude of DC charging current based on this data, increasing the current when the anode voltage surpasses a first threshold and decreasing it when the voltage reaches a second threshold, such as zero. The time-of-flight data measures the delay between emitting and receiving ultrasonic signals.

### TECHNICAL FIELD

Various embodiments relate to systems and methods for sensing a battery state, and a vehicle using such systems and methods.

### BACKGROUND

Battery cell voltage can be measured using a chip that may be multiplexed to a plurality of battery cells, connected with physical wiring, and drawing electrical power from the battery cell itself. Current measurement can be done using a current sensor that generates a difference in electric potential across the sides of a current-carrying conductor that is connected to the battery.

### BRIEF DESCRIPTION OF THE DRAWINGS

FIG. 1 is an example hybrid-electric vehicle with a battery pack.

FIG. 2 is a battery pack arrangement comprised of battery cells and battery cell monitoring and controlling systems.

FIG. 3 is an example battery pack comprised of battery cells and ultrasonic transducers.

FIG. 4 is an example ultrasonic transducer for use with a battery cell.

FIG. 5 is an example process for adjusting a current supplied to the battery based on data from the ultrasonic transducers.

FIG. 6 is an example graph illustrating change in magnitude with time-of-flight data.

### SUMMARY

An automotive power system includes a traction battery and a controller programmed to alter charging by adjusting the DC current based on data. Specifically, the system uses time-of-flight and full-cell-voltage data to detect when the anode voltage surpasses a set threshold, increasing the charging current magnitude. If the data indicates the anode voltage reaches a second threshold, potentially zero, the system reduces the current. Ultrasonic transducers are integrated to provide time-of-flight data by measuring the delay between emitting and receiving ultrasonic signals, while full-cell-voltage data monitors the voltage across the battery's anode and cathode. Additionally, temperature data can further influence adjustments.

A vehicle system includes a traction battery composed of multiple two-electrode cells and ultrasonic transducers integrated with at least one cell to collect time-of-flight data. A controller processes this data to adjust the DC current supplied to the battery, either increasing or decreasing it based on the detected ultrasonic signals. The time-of-flight data represents the duration between an ultrasonic transducer emitting and receiving a signal or between two separate transducers transmitting and receiving a signal.

A method for controlling a battery involves adjusting the charge current supplied to a battery based on time-of-flight data. This adjustment can involve either increasing or decreasing the charge current in response to the detected ultrasonic signals.

### DETAILED DESCRIPTION

Detailed embodiments are provided below. These embodiments, however, are intended solely as examples and may take various alternative forms and configurations. The accompanying figures are not drawn to scale; certain features may be exaggerated, minimized, or omitted to highlight specific details of particular components. Consequently, the structural and functional details described herein are not to be interpreted as limiting but rather as illustrative examples to guide those skilled in the art in applying the described concepts in different ways.

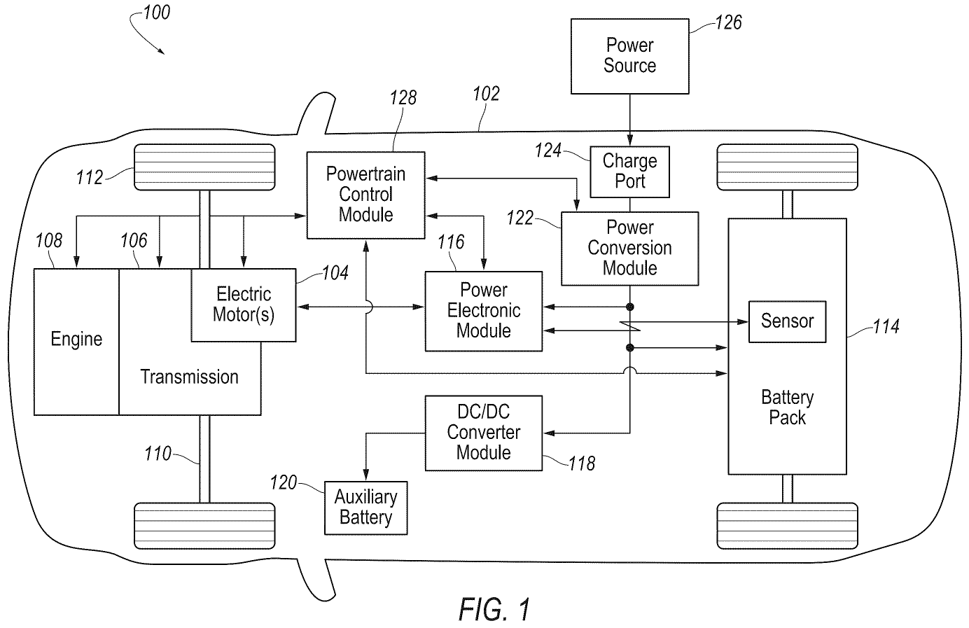

FIG. 1 depicts an example 100 of a plug-in hybrid-electric vehicle 102, which may comprise one or more electric motors 104 mechanically connected to a hybrid transmission 106. In addition, the hybrid transmission 106 is mechanically connected to an engine 108, for example an internal combustion engine. The hybrid transmission 106 may also be mechanically connected to a drive shaft 110 that is mechanically connected to the wheels 112. The electric motors 104 can provide propulsion when the engine 108 is turned on. The electric motors 104 can provide slowing capability when the engine 108 is turned off. The electric motors 104 may be configured as generators and can provide fuel economy benefits by recovering energy that would normally be lost as heat in the friction braking system.

The traction battery or battery pack 114 stores energy that can be used by the electric motors 104. A vehicle battery pack 114 typically provides a high voltage DC output. The battery pack 114 is electrically connected to a power electronics module 116. The power electronics module 116 is also electrically connected to the electric motors 104 and provides the ability to bi-directionally transfer energy between the battery pack 114 and the electric motors 104. For example, a battery pack 114 may provide a DC voltage while the electric motors 104 may require a three-phase AC current to function. The power electronics module 116 may convert the DC voltage to a three-phase AC current as required by the electric motors 104, for example, by using an inverter module. In a regenerative mode, the power electronics module 116 will convert the three-phase AC current from the electric motors 104 acting as generators to the DC voltage required by the battery pack 114, also using an inverter module or other circuitry. The methods described herein are equally applicable to a pure electric vehicle or any other device or vehicle using a battery pack.

In addition to providing energy for propulsion, the battery pack 114 may provide energy for other vehicle electrical systems. Such a system may include a DC/DC converter module 118 that converts the high voltage DC output of the battery pack 114 to a low voltage DC supply that is compatible with other vehicle loads. Other high voltage loads, such as compressors and electric heaters, may be connected directly to the high-voltage bus from the battery pack 114. In a vehicle, the low voltage systems may be electrically connected to a 12V battery 120. An all-electric vehicle may have a similar architecture but without the engine 108.

The battery pack 114 may be recharged by an external power source 126. The external power source 126 may provide AC or DC power to the vehicle 102 by electrically connecting through a charge port 124. The charge port 124 may be any type of port configured to transfer power from the external power source 126 to the vehicle 102. The charge port 124 may be electrically connected to a power conversion module 122. The power conversion module may condition the power from the external power source 126 to provide the proper voltage and current levels to the battery pack 114. In some applications, the external power source 126 may be configured to provide the proper voltage and current levels to the battery pack 114 and the power conversion module 122 may not be necessary. The functions of the power conversion module 122 may reside in the external power source 126 in some applications. The vehicle engine, transmission, electric motors, battery, power conversion and power electronics may be controlled by a powertrain control module (PCM) 128.

The battery pack 114 can include a plurality of cells that have electrodes to electrically connect the cell to circuitry. The cells are two-electrode cells. That is, the cells include two electrodes: an anode and a cathode. In examples contemplated herein, the cells each include only two electrodes. The battery parameters and status can be sensed by placing passive sensors in the battery pack or in each battery cell. A signal external to the battery can interrogate the sensor. In an example, the signal also energizes the sensor. The sensor can include radio frequency identification tag technology as well as battery sensing technology. The sensor then sends a sensed signal outside the battery pack to a receiver that is connected to vehicle circuitry.

In addition to illustrating a plug-in hybrid vehicle, FIG. 1 can illustrate a battery electric vehicle (BEV) if engine 108 is removed. Likewise, FIG. 1 can illustrate a traditional hybrid electric vehicle (HEV) or a power-split hybrid electric vehicle if components 122, 124, and 126 are removed. FIG. 1 also illustrates the high voltage system which includes the electric motor(s), the power electronics module 116, the DC/DC converter module 118, the power conversion module 122, and the battery pack 114. The high voltage system and battery pack includes high voltage components including bus bars, high voltage connectors, high voltage wires, and circuit interrupt devices.

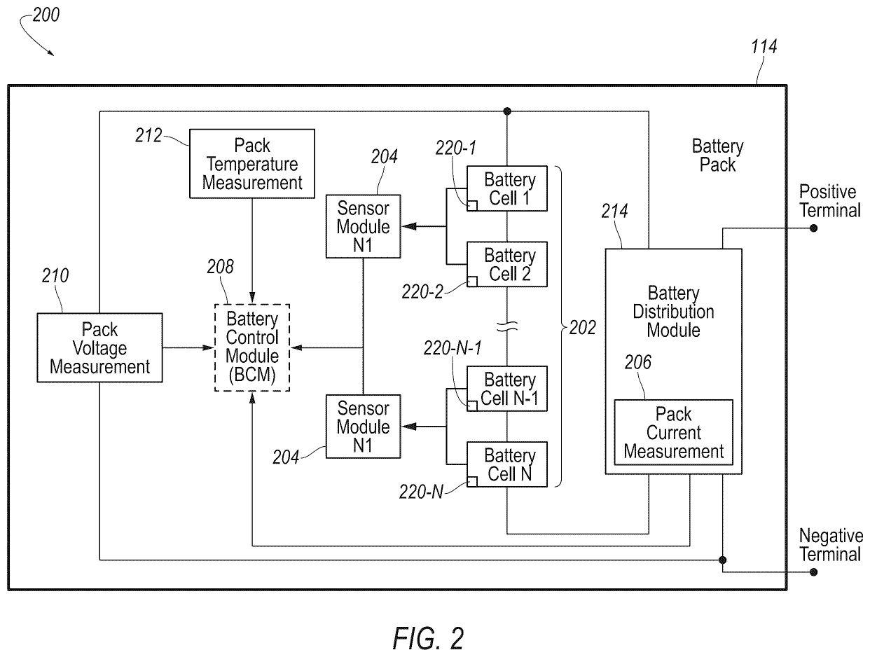

FIG. 2 shows a battery pack 200 in a series configuration of N battery cell modules 202. The battery cell modules 202 may contain a single battery cell or multiple battery cells electrically connected in parallel with the connections being made at electrodes. The battery pack, however, may be composed of any number of individual battery cells and battery cell modules connected in series or parallel or some combination thereof. A system may have one or more controllers, such as a Battery Control Module (BCM) 208 that monitors and controls the performance of the battery pack 200. The BCM 208 may monitor several battery pack level characteristics such as pack current measured by a current sensor 206, pack voltage 210, and pack temperature 212. The performance of the current sensor 206 may be helpful, in certain arrangements, to build a reliable battery monitoring system. The accuracy of the current sensor may be useful to estimate the battery state of charge and capacity. A current sensor may utilize a variety of methods based on physical principles to detect the current including a Hall Effect IC sensor, a transformer or current clamp, a resistor in which the voltage is directly proportional to the current through it, fiber optics using an interferometer to measure the phase change in the light produced by a magnetic field, or a Rogowski coil. In the event a battery cell is charging or discharging such that the current entering or exiting the battery cell exceeds a threshold, the battery control module may disconnect the battery cell via the use of a circuit interrupt device (CID) such as a fuse or circuit breaker.

The battery cell may exhibit physical changes such as, in the case of a lithium (Li) ion battery including an electrode made of metal oxides and Li ions, lithium plating as anode voltage changes. Specifically, lithium plating occurs when the measured voltage of the anode is equal to or lower than the full-cell-voltage. Full-cell-voltage is the electrochemical potential of the cell measured in volts across both electrodes in the cell. When the voltage of the anode is 0 (e.g., when the electrochemical potential of the anode is equal to the potential of metallic lithium), the lithium ions in the cell deposit onto the anode causing lithium plating.

The system 100 may monitor for lithium plating via a controller such as the BCM 208. The BCM 208 may be in communication with a sensor module 204. The sensor module 204 may measure characteristics of one or more battery cell modules 202. The battery pack 114 may utilize up to Nc sensor modules 204 to measure the characteristics of a representative sample or all of the battery cells 202. The sensor modules 204 may communicate battery cell sensors 220. Battery cell sensors 220-1, 220-2, . . . 220-N-1 and 220-N are fixed to each battery cell 1, 2, N−1, N. The battery cell sensors may, for example, be acoustic wave sensors integral with the battery cell structure. The acoustic wave sensor may include ultrasonic transducers. The battery cell sensors 220 can sense a physical property of the battery cell and produce an output signal that can be received by the sensor module 204 in response to the measured battery cell physical property. Each sensor module 204 may transfer the measurements to the BCM 208 for further processing and coordination. The sensor module 204 may transfer signals in analog or digital form to the BCM 208. The battery pack 114 may also contain a battery distribution module (BDM) 214 which controls the flow of current into and out of the battery pack 114.

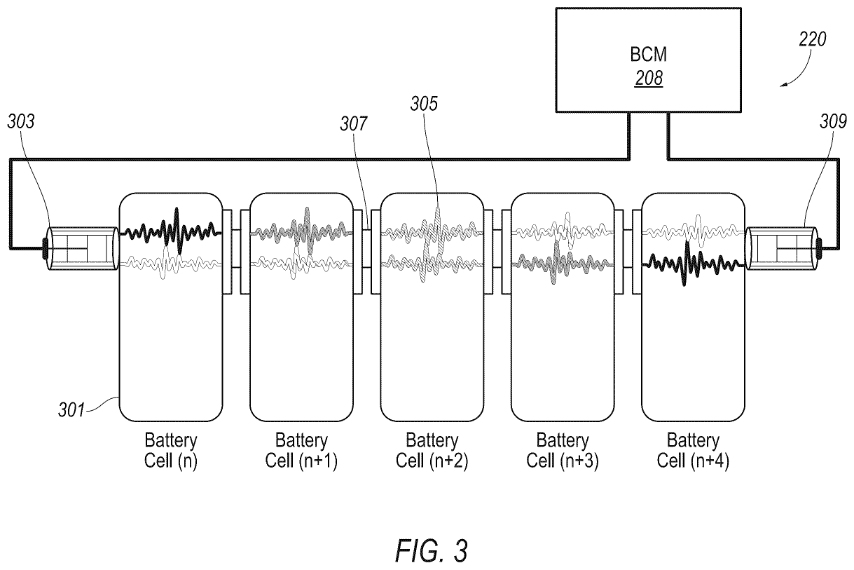

FIG. 3 shows a schematic view of a sensor 220 for a battery cell 301. The sensor 220 includes a signal input device 303 (e.g., an ultrasonic transducer) that inputs a test signal 305 at one end of the battery cell 301. The test signal 305 is an acoustic wave that travels in the battery cell 301. The structure and media of the battery cell 301 modifies or alters the test signal 305 while it travels through the battery cell. The modified signal is received by at least one output device 309 (e.g., an ultrasonic transducer). The output device 309 is positioned at an opposite end of the plurality of battery cells 301 in the illustrated example of FIG. 3. If there are multiple output devices 309, then these can be positioned at the same end of the battery cell 301 as the illustrated example or can be positioned at different sides of the battery cells 301. The output device 309 converts the propagating wave into a signal that can be wirelessly transmitted to the sensor module 204 (see, e.g., FIG. 2). The output device 309 can send the signal directly to the sensor module or can modify or interpret the received signal and send the result to the sensor module. In the case of batteries for electric vehicles, the test signal 305 propagating through the battery cell may change in velocity, phase, amplitude and/or loss, as the modulus changes, which may depend on the charge of the battery cell. This change may be directly related to the SOC and state of health (SOH) of the battery or battery cell 301. The battery cells 301 may support a plurality of ultrasonic repeaters 307 between the battery cells. The repeaters 307 may include a receiver and a transmitter configured to receive the test signal 305 as it propagates through a battery cell and transmit the test signal 305 to a second battery cell 301.

The sensors 220 may be configured to measure time-of-flight data. Time-of-flight data is a length of time for the test signal 305 to propagate throughout the battery cell 301. The time-of-flight data may be a length of time between the signal input device 303 (e.g., a first ultrasonic transducer) outputting the ultrasonic signal and the signal output device 309 (e.g., a second ultrasonic transducer) receiving the signal. The sensors may be configured to measure time-of-flight of the test signal 305 as the signal propagates from the input device 305 on a first end of the battery cell to the output device 309 on the opposite end of the battery cell (e.g., through-mode measurement). The sensors may further be configured to measure time-of-flight of the test signal 305 as the signal reflects throughout the battery cell (e.g., pulse-echo measurement).

The test signal 305 of the sensor 220 should be chosen to meet the requirement of propagation through the battery. The test signal 305 should not be completely absorbed or stopped by the battery cell 301. The signal 305 should be able to penetrate the battery cell casing, which can be a polymer or a metal, such as aluminum. Additionally, the test signal 305 should not be completely absorbed by the electrolyte in the battery. In an example, acoustic waves having a frequency in the ultrasonic spectrum (e.g., having a frequency greater than 20,000 Hz) may be used.

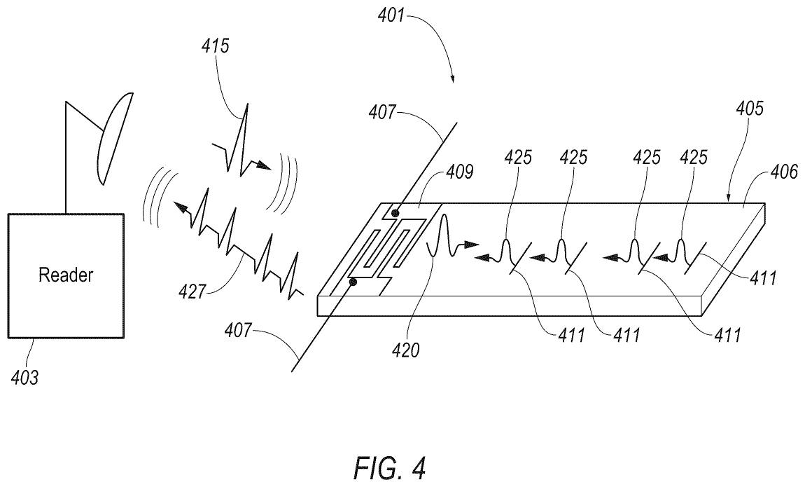

FIG. 4 shows an ultrasonic transducer sensor system 401 for a battery cell. The system 401 can be used in a mobile apparatus (e.g., a vehicle or communication device). The sensor system 401 includes a transmitter/receiver 403 that sends and receives signals in the form of ultrasonic audio signals. While described as a transmitter/receiver, it is within the scope of the present disclosure to physically separate these two parts and have a separate transmitter that is separate from the receiver. The sensor 405 includes a body 406 in which an antenna 407 is embedded and on which a transducer 409 and a plurality of wave reflectors 411 are formed. The body is a piezoelectric crystal or material that is excitable by RF signals and similarly changes shape based on applied strain caused by external factors or the environment. In operation, the transmitter/receiver 403 wirelessly sends and receives digital signals. The sent signal 415 can operate as an interrogation signal and power the sensor 405. The sent signal 415 is wirelessly received at the antenna 407, which in turn feeds the transducer 409. The transducer 409 can be an interdigital transducer. The transducer 409 converts the received signal into a wave 420 (e.g., ultrasonic wave acoustic pulses) that propagates in the body 406. The wave 420 impinges on at least some of the wave reflectors 411, which reflect the wave back 425 to the transducer 409. The transducer 409 converts the reflected wave to electrical signals and wirelessly transmits a return signal 427 to the transmitter/receiver 403. The differences in the electrical signal(s) sent to the sensor 405 and those received from the sensor 405 (e.g., the time of sending and receiving) indicate a physical characteristic of the battery cell. Such physical characteristics (e.g., time-of-flight data) may be used by the BCM 208 to calculate anode voltage. The signal sent by the transmitter/receiver 403 can be generated by the sensor module 204, the battery control module 208 or other circuitry in the vehicle. Likewise, the signal received from the transmitter/receiver 403 can be processed by the sensor module 204, the battery control module 208, or other circuitry in the vehicle to determine the physical characteristic of the battery cell.

The battery control module 208 may, for example, determine anode voltage by inputting physical characteristics (e.g., full-cell-voltage, temperature, etc.) of the battery and/or data such as time-of-flight data to an algorithm. Equation 1 is an example algorithm which the BCM 208 may utilize to determine anode voltage.

V_{anode}=(c₁+b*V_{FullCell}+a*(V_{FullCell})²)+(c₂+e*TₒF+d*(TₒF)²) Equation 1

In equation 1, V_{anode} is the voltage as measured at the anode, V_{FullCell} is the voltage measured across the anode and cathode, and TₒF is the time-of-flight data of the signal 305. Additionally, a, b, c, d, and e are solvable roots which can be determined during a testing and development phase of the system. The roots may be found by solving the quadratic relationships presented in equation 1 after measuring the time-of-flight data and the full-cell voltage.

According to equation 1, the anode voltage may increase as the time-of-flight of the test signal 305 increases. A change in time-of-flight of the test signal 305 may be a result of changes to the electrochemical potential of the battery cell 301. This could be simulated by the introduction of an acoustic barrier, etc. For example, an acoustic barrier may be introduced to a cell 301 (e.g., a barrier may be introduced at the repeater 307 in a multiple-cell battery). The acoustic barrier may increase time-of-flight of the test signal 305 as a result of the time required for the test signal 305 to propagate through the barrier, depending on the material from which the barrier is manufactured. Accordingly, the increase in time-of-flight data resulting from the introduction of the barrier would increase the value of V_{anode} for any system using the techniques described herein and result in an increase in the charge current magnitude, provided the value exceeds a corresponding threshold.

In order to mitigate lithium plating when the anode voltage approaches 0 during charging of the battery 114 with a DC current, the BCM 208 may adjust a magnitude of the DC current. The BCM 208 may increase or decrease a magnitude of the DC current (e.g., measured in Amperes) based on the relationship of the anode voltage to a plurality of predetermined thresholds. For example, the threshold may be a first threshold. If the anode voltage exceeds the first threshold (e.g., 2.0 Volts) the BCM 208 may increase a magnitude of the DC current whereas if the anode voltage does not exceed the first threshold the BCM 208 may maintain the magnitude of the DC current. The first threshold as well as the amount to increase the magnitude of the DC current may be predetermined to increase a rate of charging for the battery 114.

The BCM 208 may increase or decrease a magnitude of the DC current based on the relationship of the anode voltage to a second threshold. Similar to the first threshold, the second threshold may be predetermined. The second threshold may be predetermined to mitigate lithium plating. The BCM 208 may reduce the DC current being supplied to the battery 114 in response to determining that the anode voltage has fallen to or below 0 Volts. That is, if the BCM determines that the anode voltage is 0 or has fallen below 0, the BCM 208 may reduce the DC current by a predetermined amount selected to reduce the rate of lithium plating occurring at the anode during charging.

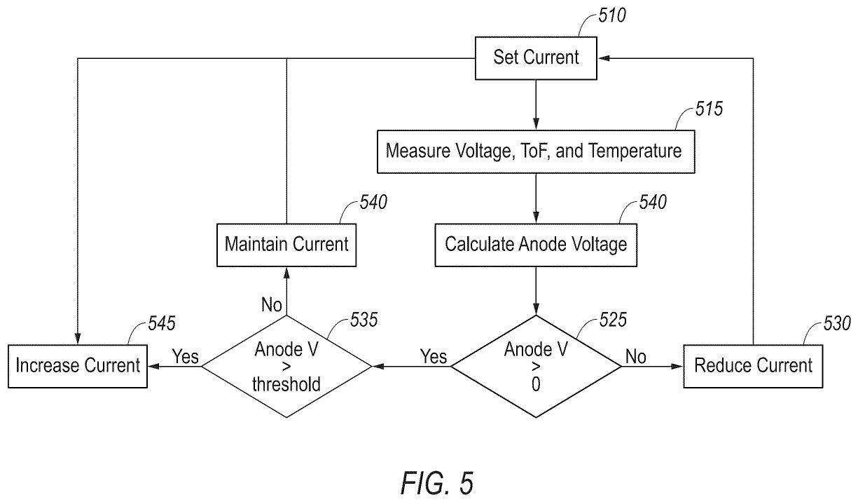

FIG. 5 is a flowchart illustrating an example process 500 for adjusting a magnitude of DC current being supplied to a traction battery 114 during recharging. A computer (controller) such as the BCM 208 may store executable instructions for performing the steps of the process 500 and/or programming can be implemented in structures such as mentioned above. The process 500 may continue for as long as the vehicle remains on.

The process begins in block 510 in which the computer sets the DC current supply to the battery 114 during recharging. The magnitude of current may be based on a predetermined standard recharging level and/or may be based on an adjustment having occurred during a previous iteration of the process 500 as will be described below.

Next, in block 515, the computer measures full-cell voltage, time-of-flight data, and temperature as described above. The computer may actuate sensors 220 to measure the full-cell voltage, time-of-flight data, and temperature and receive the data from the sensors 220.

Next, in block 520, the computer calculates anode voltage using the data measured in the block 515. The computer may input the data to, for example, equation 1 to determine the anode voltage.

Next, in block 525 the computer determines whether the anode voltage has met the second threshold as described above. If the anode voltage has met or fallen below the second threshold, the process 500 continues to block 530. Otherwise, the process continues to block 535.

In the block 530, the computer has determined that the anode voltage has met or fallen below the second threshold. The computer then adjusts the supply of current according to a predetermined (e.g., stored in memory) level. The process then returns to the block 510 and the computer sets the current level to the reduced level.

In the block 535, the computer has determined that the anode volage has not met or fallen below the second threshold. The computer then determines whether the anode voltage has exceeded the first threshold as described above. If the anode voltage has not exceeded the first threshold the process 500 continues to a block 540. Otherwise, the process continues to block 545.

In the block 540, the computer has determined that the anode voltage has not exceeded the first threshold. The computer maintains the current level and the process 500 returns to the block 510.

In the block 545, the computer has determined that the anode voltage has exceeded the first threshold. The computer increases the current as described above by a predetermined level selected to increase the rate of charging. The process then returns to the block 510.

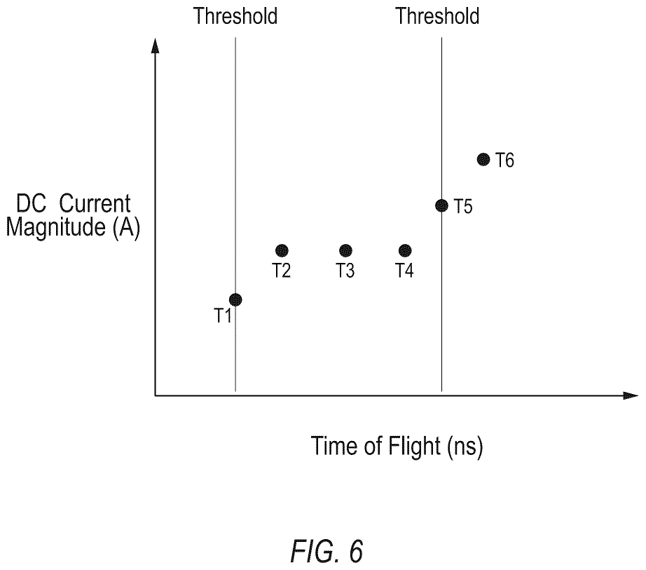

FIG. 6 shows an example graphical illustration of the change in magnitude of DC current as time-of-flight data changes based on the systems described herein (e.g., the process 500). Time-of-flight data of the test signal 305 as measured in nanoseconds (ns) is shown on the horizontal axis. The magnitude of the current being supplied to the traction battery 114 as measured in amperes (A) is shown on the vertical axis. T1-T6 represent time-of-flight data and how the magnitude of DC current is adjusted based on the time-of-flight-data. The time-of-flight data may, in combination with full-cell-voltage data, be indicative of the anode voltage (e.g., as per equation 1). At T1, the time-of-flight data has decreased to the point of being indicative of the anode voltage meeting the second threshold (e.g., 0V), and the magnitude of the current is a correspondingly lower value (e.g., as a result of process 500, BMC 208 decreases the current). At T2-T4, the time-of-flight increases but the anode voltage has not yet met the first threshold, therefore the BCM 208 maintains the magnitude of the DC current. At T5 the time-of-flight data has increased such that the anode voltage has met the first threshold and the BCM 208 increases the current magnitude. Similarly, at T6 the time-of-flight data has increased further (further increasing the value of the anode voltage) and thus the BCM 208 further increases the magnitude of the DC current.

Computing devices such as those discussed herein generally each include commands executable by one or more computing devices such as those identified above, and for carrying out blocks or steps of processes described above. For example, process blocks discussed above may be embodied as computer executable commands.

Computer executable commands may be compiled or interpreted from computer programs created using a variety of programming languages and/or technologies, including, without limitation, and either alone or in combination, Java™, C, C++, Python, Julia, SCALA, Visual Basic, Java Script, Perl, HTML, etc. In general, a processor (i.e., a microprocessor) receives commands (i.e., from a memory, a computer readable medium, etc.) and executes these commands, thereby performing one or more processes, including one or more of the processes described herein. Such commands and other data may be stored in files and transmitted using a variety of computer readable media. A file in a computing device is generally a collection of data stored on a computer readable medium, such as a storage medium, a random access memory, etc.

A computer-readable medium (also referred to as a processor-readable medium) includes any non-transitory (i.e., tangible) medium that participates in providing data (i.e., instructions) that may be read by a computer 104 (i.e., by a processor of a computer 104). Such a medium may take many forms, including, but not limited to, non-volatile media and volatile media. Instructions may be transmitted by one or more transmission media, including fiber optics, wires, wireless communication, including the internals that comprise a system bus coupled to a processor of a computer 104. Common forms of computer-readable media include, for example, RAM, a PROM, an EPROM, a FLASH-EEPROM, any other memory chip or cartridge, or any other medium from which a computer 104 can read.

With regard to the media, processes, systems, methods, etc. described herein, it should be understood that, although the steps or blocks of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments and should in no way be construed so as to limit the claimed invention.

Use of in response to, based on, and upon determining herein indicates a causal relationship, not merely a temporal relationship. “Based on” or “in response to” can mean based at least partly on or at least partly in response to unless explicitly stated otherwise.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the claimed invention.

What is claimed is:

1. An automotive power system comprising:
a traction battery; and
a controller programmed to, during charging of the traction battery with a DC current and responsive to time-of-flight and full-cell-voltage data for the traction battery being indicative of an anode voltage exceeding a threshold, increase a magnitude of the DC current.

2. The system of claim 1, wherein the controller is further programmed to, during the charging and responsive to the time-of-flight and full-cell-voltage data being indicative of the anode voltage achieving a second threshold, reduce the magnitude.

3. The system of claim 2, wherein the second threshold is zero.

4. The system of claim 1 further comprising a plurality of ultrasonic transducers arranged with the traction battery and configured to output ultrasonic signals.

5. The system of claim 4, wherein the time-of-flight data represents a length of time between at least one of the ultrasonic transducers outputting and receiving one of the ultrasonic signals.

6. The system of claim 4, wherein the time-of-flight data represents a length of time between a first of the ultrasonic transducers outputting one of the ultrasonic signals and a second of the ultrasonic transducers receiving the one of the ultrasonic signals.

7. The system of claim 1, wherein the full-cell-voltage data is a voltage level measured with respect to an anode and a cathode of the traction battery.

8. The system of claim 1 further comprising, responsive to temperature data for the traction battery being further indicative of the anode voltage exceeding the threshold, increasing the magnitude.

9. A vehicle system comprising:
a traction battery including a plurality of two-electrode cells and ultrasonic transducers arranged with at least one of the cells and configured to detect time-of-flight data; and
a controller configured to alter a magnitude of DC current being supplied to the traction battery according to the time-of-flight data.

10. The vehicle system of claim 9, wherein the altering includes increasing.

11. The vehicle system of claim 9, wherein the altering includes decreasing.

12. The system of claim 9, wherein the time-of-flight data is a length of time between at least one of the ultrasonic transducers outputting and receiving an ultrasonic signal.

13. The system of claim 9, wherein the time-of-flight data is a length of time between a first of the ultrasonic transducers outputting an ultrasonic signal and a second of the ultrasonic transducers receiving the ultrasonic signal.

14. A method for control a battery, comprising:
adjusting a magnitude of charge current to a battery responsive to time-of-flight data.

15. The method of claim 14, wherein the adjusting includes increasing.

16. The method of claim 14, wherein the adjusting includes decreasing.
